(19) United States
(12) Patent Application Publication
(10) Pub. No.: US 2015/0276884 A1
(43) Pub. Date: Oct. 1, 2015

(54) LITHIUM-ION SECONDARY BATTERY SYSTEM AND STATUS DIAGNOSTIC METHOD OF LITHIUM-ION SECONDARY BATTERY

(71) Applicant: Hitachi, Ltd., Tokyo (JP)

(72) Inventors: Shinsuke ANDOH, Tokyo (JP); Atsuhiko OONUMA, Tokyo (JP); Takashi KAMIJOH, Tokyo (JP)

(73) Assignee: HITACHI, LTD., Tokyo (JP)

(21) Appl. No.: 14/607,641

(22) Filed: Jan. 28, 2015

(30) Foreign Application Priority Data
Mar. 31, 2014 (JP) 2014-070830

(51) Int. Cl. G01R 31/36; H01M 10/48

(52) U.S. Cl. CPC G01R 31/3627; H01M 10/482; G01R 31/3679

(57) ABSTRACT

The present invention is a lithium-ion secondary battery system having a lithium-ion secondary battery, potential measuring sections, a voltage applying section, an electric current measuring section, and a switching section. The lithium-ion secondary battery has a positive electrode reference electrode, a negative electrode reference electrode, a positive electrode, and a negative electrode; when the positive electrode reference electrode and the negative electrode reference electrode are connected with the switching section, an electric current when a voltage is applied between the positive electrode reference electrode and the negative electrode reference electrode with the voltage applying section is measured with the electric current measuring section; and when the positive electrode reference electrode and the positive electrode are connected and the negative electrode reference electrode and the negative electrode are connected with the switching section, the potentials of the positive electrode and the negative electrode are measured with the potential measuring sections.

### BACKGROUND

The present invention relates to a lithium-ion secondary battery system and a status diagnostic method of a lithium-ion secondary battery.

It has heretofore been known that reference electrodes are arranged in a lithium-ion secondary battery with the aim of measuring a positive electrode potential and a negative electrode potential respectively. With regard to a lithium-ion secondary battery having reference electrodes, the following technology is disclosed in Japanese Unexamined Patent Application Publication No. 2006-179329. A lithium secondary battery (electrochemical cell) 100 has, in addition to a positive electrode 120 and a negative electrode 130, a positive electrode side reference electrode 125 arranged in the vicinity of the positive electrode 120 and a negative electrode side reference electrode 135 arranged in the vicinity of the negative electrode 130. Further, the positive electrode 120 and the positive electrode side reference electrode 125 are isolated from each other through an electrolyte in the state of interposing a first separator 141, the negative electrode 130 and the negative electrode side reference electrode 135 are isolated from each other through the electrolyte in the state of interposing a second separator 143, and the positive electrode 120 and the like and the negative electrode 130 and the like are isolated from each other through the electrolyte in the state of interposing a third separator 145.

### SUMMARY

As described in Japanese Unexamined Patent Application Publication No. 2006-179329, a reference electrode is aimed at measuring a positive electrode potential or a negative electrode potential. Japanese Unexamined Patent Application Publication No. 2006-179329 discloses a configuration of measuring a potential between a reference electrode and a positive electrode and/or a negative electrode. It has been obvious that the degradation of a lithium-ion secondary battery is caused not only by the degradation of an electrode active material but also by the change of a lithium ion concentration in an electrolyte as a cause. As a method of measuring a lithium ion concentration in an electrolyte, a method of measuring by disassembling a battery or extracting apart of an electrolyte is generally used. In the technology of Japanese Unexamined Patent Application Publication No. 2006-179329, a mechanism of measuring a lithium ion concentration in an electrolyte by switching the connection condition of a positive electrode, a positive electrode side reference electrode, a negative electrode, and a negative electrode side reference electrode does not exist and hence it is difficult to nondestructively measure a lithium ion concentration in an electrolyte.

An object of the present invention is to nondestructively grasp a lithium ion concentration in an electrolyte.

Features of the present invention for solving the aforementioned problem are as follows for example.

A lithium-ion secondary battery system having a lithium-ion secondary battery, potential measuring sections, a voltage applying section, an electric current measuring section, and a switching section, wherein the lithium-ion secondary battery has a positive electrode reference electrode, a negative electrode reference electrode, a positive electrode, and a negative electrode; when the positive electrode reference electrode and the negative electrode reference electrode are connected with the switching section, an electric current when a voltage is applied between the positive electrode reference electrode and the negative electrode reference electrode with the voltage applying section is measured with the electric current measuring section; and when the positive electrode reference electrode and the positive electrode are connected and the negative electrode reference electrode and the negative electrode are connected with the switching section, the potentials of the positive electrode and the negative electrode are measured with the potential measuring sections.

The present invention makes it possible to nondestructively grasp a lithium ion concentration in an electrolyte. The problem, configuration, and effect other than described above will be obvious through the explanations on the following embodiments.

### BRIEF DESCRIPTION OF THE DRAWINGS

FIG. 1 is an explanatory view showing a general configuration of a lithium-ion secondary battery system according to an embodiment of the present invention;

FIG. 2 is an explanatory view showing a general configuration of a lithium-ion secondary battery system according to an embodiment of the present invention;

FIG. 3 is a graph showing a calibration curve for obtaining the relationship between an electric current and a lithium ion concentration in an electrolyte;

FIG. 4 is an explanatory view showing a general configuration of a lithium-ion secondary battery system according to an embodiment of the present invention;

FIG. 5 is an explanatory view showing a general configuration of a lithium-ion secondary battery system according to an embodiment of the present invention;

FIG. 6 is an explanatory view showing a general configuration of a lithium-ion secondary battery system according to an embodiment of the present invention;

FIG. 7 is an explanatory, view showing a general configuration of a lithium-ion secondary battery system according to another embodiment of the present invention;

FIG. 8 is a graph showing an example of Arrhenius plot showing the relationship between an electric current and the reciprocal of a battery temperature;

FIG. 9 is an explanatory view showing a general configuration of a lithium-ion secondary battery system according to an embodiment of the present invention; and

FIG. 10 is an explanatory view showing a general configuration of a lithium-ion secondary battery system according to an embodiment of the present invention.

### DETAILED DESCRIPTION

Embodiments according to the present invention are hereunder explained in reference to drawings and others. The following explanations merely show the concrete examples of the contents of the present invention and the present invention is not limited to the explanations and can be variously modified and amended by a person skilled in the art within the range of the technological thought disclosed in the present specification. Further, in all the drawings for explaining the present invention, those having an identical function are represented by an identical symbol and the repetitive explanations are omitted in some cases.

### First Embodiment

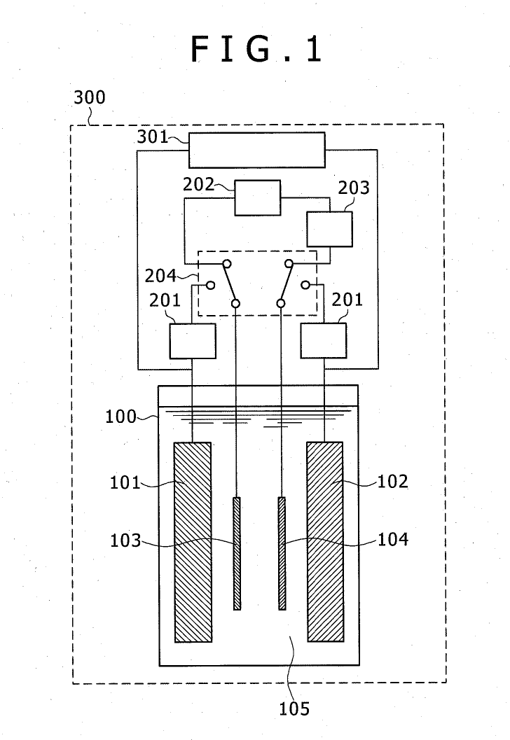

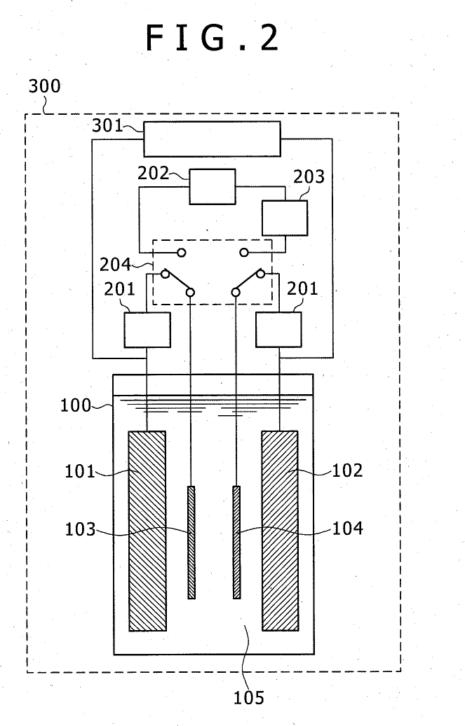

Embodiments according to the present invention are explained in reference to FIGS. 1 and 2. Each of FIGS. 1 and 2 is an explanatory view showing a general configuration of a lithium-ion secondary battery system according to an embodiment of the present invention.

A lithium-ion secondary battery system 300 has a lithium-ion secondary battery 100 as an electrochemical cell, potential measuring sections 201, a voltage applying section 202, an electric current measuring section 203, and a switching section 204. The lithium-ion secondary battery 100 has a positive electrode 101, a negative electrode 102, a positive electrode reference electrode 103, a negative electrode reference electrode 104, and an electrolyte 105. The positive electrode 101 and the negative electrode 102 are electrically isolated from each other by a separator not shown in the figures in order to prevent the positive electrode 101 and the negative electrode 102 from short-circuiting. The positive electrode 101, the negative electrode 102, the positive electrode reference electrode 103, and the negative electrode reference electrode 104 are immersed in the electrolyte 105. The voltage applying section 202, the electric current measuring section 203, and the switching section 204 are arranged in the connection path between the positive electrode reference electrode 103 and the negative electrode reference electrode 104.

A lithium metal oxide is used for a positive electrode active material in the positive electrode 101 and a carbon material such as graphite is used for a negative electrode active material in the negative electrode 102. The electrolyte 105 includes lithium salt and a solvent such as ethylene carbonate.

The lithium-ion secondary battery 100 is electrically connected to a charge-discharge control section 301. The charge and discharge of the lithium-ion secondary battery 100 are controlled by the charge-discharge control section 301 in response to a request from the exterior. The lithium-ion secondary battery 100 can be configured by connecting two or more lithium-ion secondary batteries in series or parallel in accordance with a requested output or capacity.

FIG. 1 is a view showing the relation of connection of the switches in the switching section 204 when a lithium ion concentration in the electrolyte is measured and FIG. 2 is a view showing the relation of connection of the switches in the switching section 204 when a potential is measured. When a lithium ion concentration in the electrolyte is measured, as shown by the switching section 204 in FIG. 1, the voltage applying section 202 and the electric current measuring section 203 are connected so as to be arranged between the positive electrode reference electrode 103 and the negative electrode reference electrode 104. In FIG. 1, the positive electrode reference electrode 103 and the negative electrode reference electrode 104 are connected with the switching section 204. A lithium ion concentration in the electrolyte can be measured by measuring an electric current with the electric current measuring section 203 when a voltage is applied between the positive electrode reference electrode 103 and the negative electrode reference electrode 104 with the voltage applying section 202.

Further, when the potentials of the positive electrode 101 and the negative electrode 102 are measured with the potential measuring sections 201, as shown in the switching section 204 of FIG. 2, the two potential measuring sections 201 are connected so as to be arranged between the positive electrode 101 and the positive electrode reference electrode 103 and between the negative electrode 102 and the negative electrode reference electrode 104 respectively. In FIG. 2, with the switching section 204, the positive electrode reference electrode 103 is connected to the positive electrode 101 and the negative electrode reference electrode 104 is connected to the negative electrode 102. On this occasion, the potentials of the positive electrode 101 and the negative electrode 102 are measured with the potential measuring sections 201.

The lithium-ion secondary battery 100 is electrically connected also to the switching section 204 in parallel with the charge-discharge control section 301. By switching the connection as shown in FIGS. 1 and 2 with the switching section 204, it is possible to measure the potential of the positive electrode 101 and/or the potential of the negative electrode 102 and measure a lithium ion (Li⁺) concentration (mol/L) in the electrolyte 105. By measuring the potential difference between the positive electrode 101 and the positive electrode reference electrode 103 and/or between the negative electrode 102 and the negative electrode reference electrode 104 with the potential measuring sections 201, the potential of the positive electrode 101 and/or the potential of the negative electrode 102 can be measured. The lithium ion concentration in the electrolyte 105 can be computed from an electric current value measured with the electric current measuring section 203 by giving a potential gradient and thereby applying electric current between the positive electrode reference electrode 103 and the negative electrode reference electrode 104 with the voltage applying section 202. By measuring the lithium ion (Li⁺) concentration (mol/L) in the electrolyte 105, the degradation mode of the battery, namely the factor of the degradation of the battery, as to whether the electrodes or the electrolyte are/is degraded can be specified.

The principle of measuring a lithium ion concentration in the electrolyte 105 according to the first embodiment of the present invention is explained as follows on the basis of the case of using lithium titanate for the reference electrodes (the positive electrode reference electrode 103 and the negative electrode reference electrode 104). When a voltage is applied between the positive electrode reference electrode 103 and the negative electrode reference electrode 104, the reactions respectively following the expression (1) at the anode and the expression (2) at the cathode proceed.

[Num 1]

Li₇Ti₅O₁₂→Li₄Ti₅O₁₂+3Li⁺+3e⁻ (1)

[Num 2]

Li₄Ti₅O₁₂+3Li⁺+3e⁻→Li₇Ti₅O₁₂ (2)

The number of lithium ions and the number of electrons are in the relationship of 1:1. When a sufficiently large voltage is applied therefore, the velocity of the lithium ions flowing in the electrolyte 105 comes to be the electric current value and hence, by measuring the electric current accompanying the reactions, it is possible to compute the quantity of the lithium ions in the electrolyte 105 existing between the positive electrode reference electrode 103 and the negative electrode reference electrode 104. The relationship follows the Cottrell equation shown by the expression (3).

[Num 3]

i=nFACD^{0.5}π^{-0.5}t^{-0.5} (3)

Here, i represents an electric current, n a reacted electron number, F a Faraday constant, A an electrode area, C a lithium ion concentration, ID a diffusion coefficient, and t a time having elapsed after a voltage is applied. From the expression (3), an electric current bears a linear relationship with a lithium ion concentration by setting t at a given time and hence it is possible to compute a lithium ion concentration in the electrolyte 105 by computing a calibration curve showing the relationship between a lithium ion concentration C in the electrolyte 105 and an electric current value i at a given time t beforehand and then measuring an electric current. In this way, it is possible to compute a lithium ion concentration in the electrolyte 105 by measuring an electric current flowing when voltages are applied to the electrodes and computing in accordance with the expression (3). Since the operation in the measurement of a lithium ion concentration includes the application of voltages from the exterior of a battery and the measurement of an electric current, a lithium ion concentration in the electrolyte 105 can be measured nondestructively.

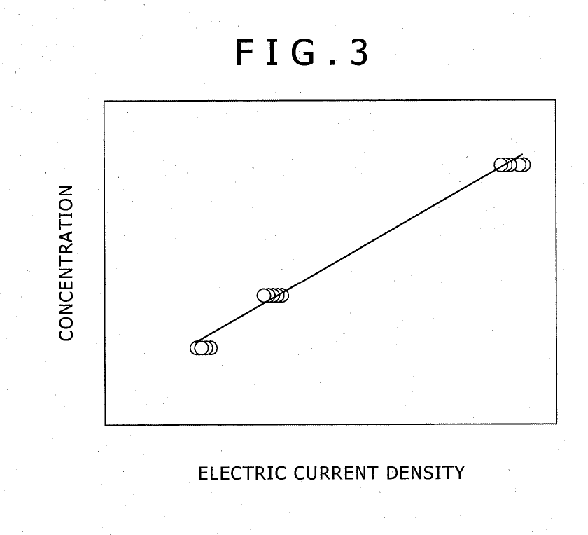

FIG. 3 is a graph showing an example of a calibration curve for obtaining the relationship between an electric current and a lithium ion concentration in an electrolyte. The relationship between an electric current and a lithium ion concentration in the electrolyte 105 represents a response having linearity and the concentration of the electrolyte 105 can be measured with a high degree of accuracy. When the positive electrode reference electrode 103 and the negative electrode reference electrode 104 are used for a long period of time, the quantities of the lithium ions filled at the positive electrode reference electrode 103 and the negative electrode reference electrode 104 are biased and the respective detection accuracies of the positive electrode potential and the negative electrode potential may possibly reduce but, by the first embodiment according to the present invention, the positive electrode potential and the negative electrode potential can be detected with a high degree of accuracy.

By applying voltage, lithium ions move between the positive electrode reference electrode 103 and the negative electrode reference electrode 104 by the reactions of the expressions (1) and (2) and hence the quantities of lithium filled at the respective reference electrodes of the positive electrode reference electrode 103 and the negative electrode reference electrode 104 are biased. In an ordinary active material such as LiCoO₂, LiMn₂O₄, or LiNiₓCo_{y}Mn_{z}O₂, a potential varies largely depending on a filled lithium quantity and hence a potential difference is caused if the filled lithium quantity is different between the positive electrode reference electrode 103 and the negative electrode reference electrode 104. As a result, a bias is caused to an applied voltage, hence control for maintaining a constant applied voltage is required additionally, and therefore the control may possibly become complex. Consequently, it is preferable to select a material allowing a potential to be hardly changeable against a filled lithium quantity, for example lithium titanate or olivine-type lithium iron phosphate, as a material for the positive electrode reference electrode 103 and the negative electrode reference electrode 104. Further, the positive electrode reference electrode 103 and the negative electrode reference electrode 104 may preferably include an identical material in order to make the potential difference close to zero or desirably unlimitedly close to zero.

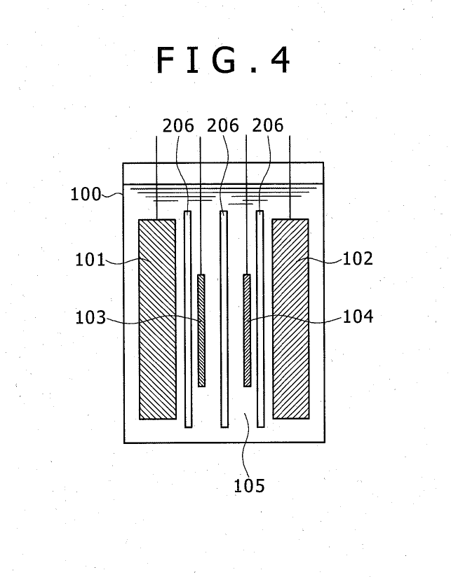

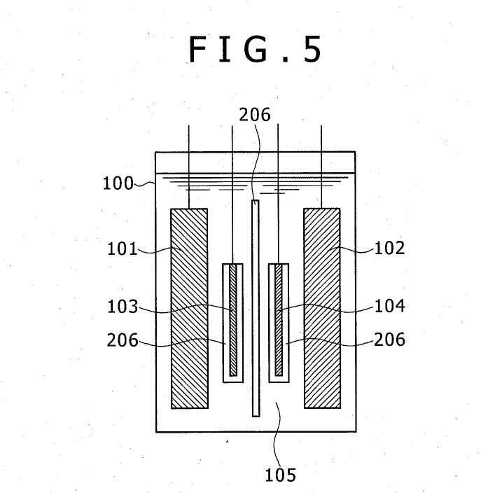

The two reference electrodes are preferably arranged in the manner of facing each other while a separator 206 is interposed in between as shown in FIGS. 4 and 5 so that an electric current may be measured accurately, the moving distance of lithium ions may be linear, and electric insulation may be secured.

Each of FIGS. 4 and 5 is an explanatory view showing a general configuration of a lithium-ion secondary battery system according to an embodiment of the present invention. In FIG. 4, separators 206 are arranged respectively between a positive electrode 101, a negative electrode 102, a positive electrode reference electrode 103, and a negative electrode reference electrode 104. In FIG. 5, a separator 206 is arranged between a positive electrode 101 and a negative electrode 102, and a positive electrode reference electrode 103 and a negative electrode reference electrode 104 are covered with separators 206. In either of the cases, a positive electrode reference electrode 103 and a negative electrode reference electrode 104 are arranged in a manner of facing each other while a separator 206 is interposed in between.

The shape of a reference electrode is not particularly limited but, in order to accurately grasp an electrode area as shown in the expression (3), it is preferable to select not a linear shape but a tabular shape from the viewpoint of making it easier to obtain an area where the two reference electrodes face each other.

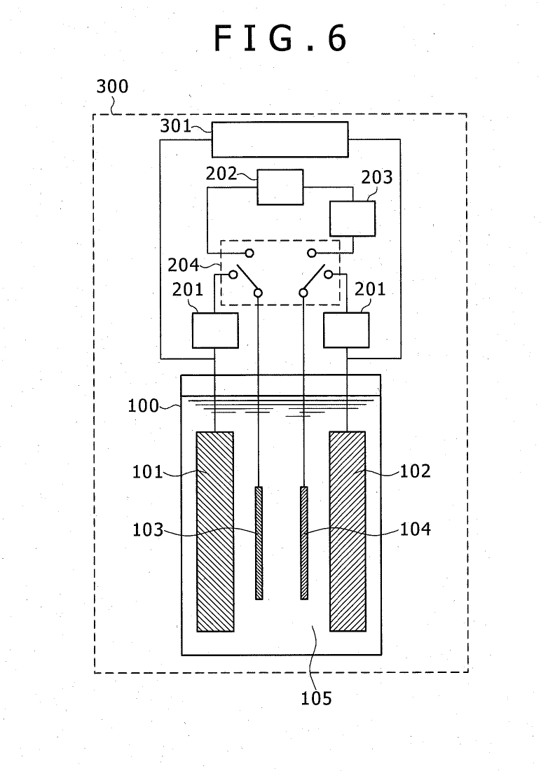

A configuration of turning off switches, namely a state of non-measurement, is shown in FIG. 6. FIG. 6 is an explanatory view showing a general configuration of a lithium-ion secondary battery system according to an embodiment of the present invention. Usually the system is in the state of switched off, namely of measuring neither positive and negative potentials nor a lithium ion concentration in an electrolyte, and when positive and negative potentials or a lithium ion concentration are/is measured, measurement can be carried out as shown in FIG. 1 or 2 at a desired timing.

### Second Embodiment

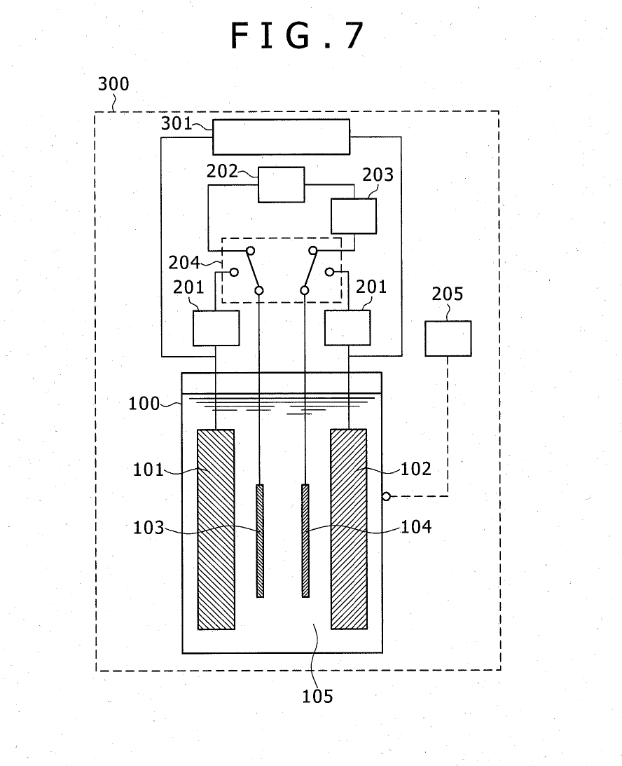

Another embodiment according to the present invention is explained in reference to FIG. 7. FIG. 7 shows a configuration of preparing a temperature measuring section 205 in a lithium-ion secondary battery system 300. The temperature measuring section 205 measures the temperature of a lithium-ion secondary battery 100. the present embodiment, an electric current between a positive electrode reference electrode 103 and a negative electrode reference electrode 104 is corrected on the basis of a temperature of the lithium-ion secondary battery measured by the temperature measuring section 205.

The operation temperature of the lithium-ion secondary battery 100 is constant when it is operated at constant input and output but varies when charge or discharge operation stops or an inputted or outputted electric current varies. Since the ion conductivity in an electrolyte 105 depends on temperature, even when the concentration of the electrolyte 105 is constant, by the variation of the temperature in the lithium-ion secondary battery 100, an electric current value measured with the electric current measuring section 203 also varies.

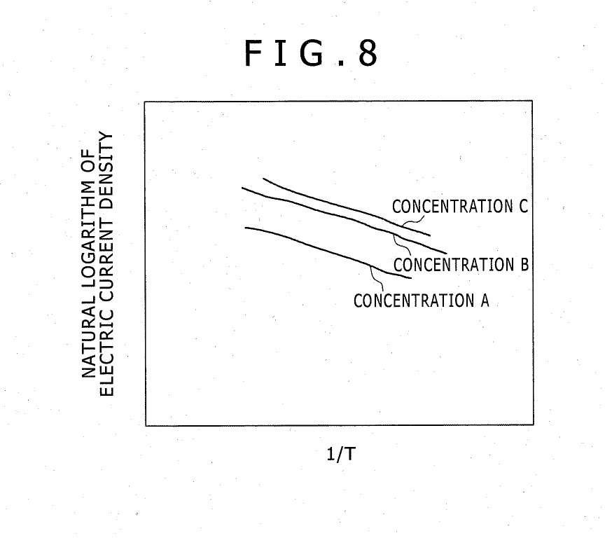

FIG. 8 is a graph showing an example of Arrhenius plot showing the relationship between an electric current and the reciprocal of a battery temperature. A, B, and C in FIG. 8 represent the magnitudes of lithium ion concentrations and the magnitudes of the lithium ion concentrations satisfy the relation of A<B<C. A represents the state of the lowest lithium ion concentration and C represents the state of the highest lithium ion concentration. According to the expression (3), the diffusion constant D has temperature dependency. As shown in FIG. 8, the relationship between a battery temperature and an electric current follows the Arrhenius law and hence the relationship between the value of the natural logarithm of an electric current and the reciprocal of a temperature becomes linear. The inclination is not changed even when a concentration varies and hence, by measuring a battery temperature and correcting an electric current value by the temperature through the Arrhenius law, a concentration can be measured accurately even at an arbitrary temperature.

### Third Embodiment

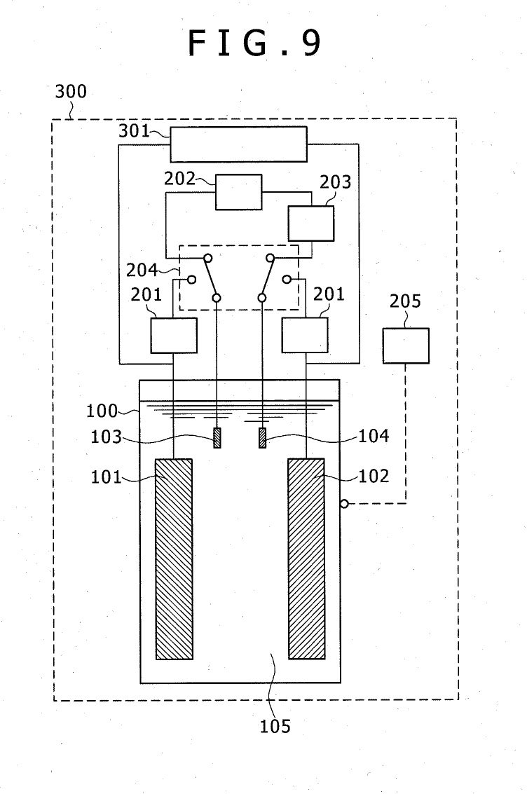

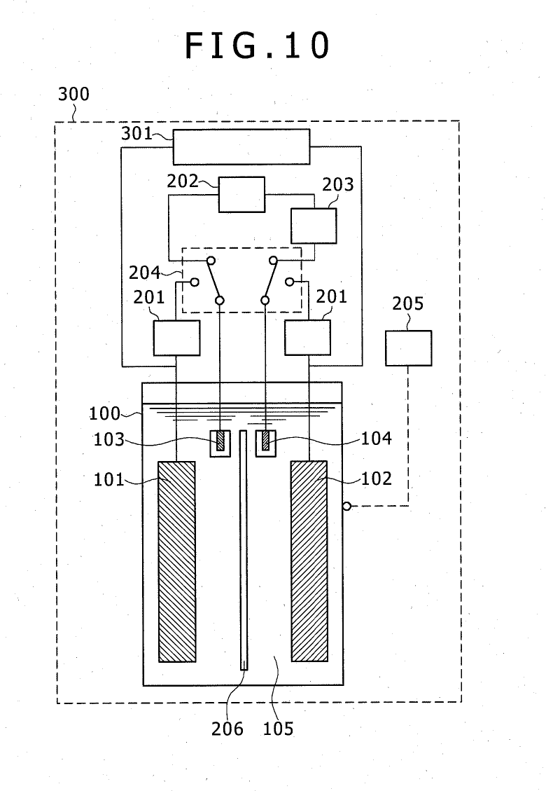

Other embodiments according to the present invention are further explained in reference to FIGS. 9 and 10. Each of FIGS. 9 and 10 is an explanatory view showing a general configuration of a lithium-ion secondary battery system according to an embodiment of the present invention and shows the configuration of arranging a positive electrode reference electrode 103 and a negative electrode reference electrode 104 outside a positive electrode 101 and a negative electrode 102 facing each other. In FIG. 10, in addition to the configuration of FIG. 9, a separator 206 is arranged between the positive electrode 101 and the negative electrode 102, and the positive electrode reference electrode 103 and the negative electrode reference electrode 104 are covered with separators 206.

The positive electrode reference electrode 103 and the negative electrode reference electrode 104 are configured so as to hardly interfere with the movement of lithium ions when a lithium-ion secondary battery 100 is charged and discharged and be hardly susceptible to the influence of an electric field accompanying charge and discharge and hence it is possible to improve potential measurement accuracy during charge and discharge.

1. A lithium-ion secondary battery system comprising:
a lithium-ion secondary battery;
potential measuring sections;
a voltage applying section;
an electric current measuring section; and
a switching section, wherein the lithium-ion secondary battery has a positive electrode reference electrode, a negative electrode reference electrode, a positive electrode, and a negative electrode;
when the positive electrode reference electrode and the negative electrode reference electrode are connected with the switching section, an electric current when a voltage is applied between the positive electrode reference electrode and the negative electrode reference electrode with the voltage applying section is measured with the electric current measuring section; and
when the positive electrode reference electrode and the positive electrode are connected and the negative electrode reference electrode and the negative electrode are connected with the switching section, the potentials of the positive electrode and the negative electrode are measured with the potential measuring sections.

2. The lithium-ion secondary battery system according to claim 1, wherein the positive electrode reference electrode and the negative electrode reference electrode include an identical material.

3. The lithium-ion secondary battery system according to claim 1, wherein the material of the positive electrode reference electrode and the negative electrode reference electrode is lithium titanate or olivine-type lithium iron phosphate.

4. The lithium-ion secondary battery system according to claim 1, wherein the positive electrode reference electrode and the negative electrode reference electrode have tabular shapes.

5. The lithium-ion secondary battery system according to claim 1,
wherein the lithium-ion secondary battery has a separator; and the positive electrode reference electrode and the negative electrode reference electrode are arranged in a manner of facing each other while a separator is interposed in between.

6. The lithium-ion secondary battery system according to any claim 1,
wherein the lithium-ion secondary battery system has a temperature measuring section to measure the temperature of the lithium-ion secondary battery; and
the electric current between the positive electrode reference electrode and the negative electrode reference electrode is corrected on the basis of the temperature of the lithium-ion secondary battery measured with the temperature measuring section.

7. The lithium-ion secondary battery system according to claim 1,
wherein the positive electrode and the negative electrode are arranged in a manner of facing each other; and
the positive electrode reference electrode and the negative electrode reference electrode are arranged outside the positive electrode and the negative electrode facing each other.

8. A status diagnostic method of a lithium-ion secondary battery by a lithium-ion secondary battery system having the lithium-ion secondary battery, potential measuring sections, a voltage applying section, an electric current measuring section, and a switching section,
wherein the lithium-ion secondary battery has a positive electrode reference electrode, a negative electrode reference electrode, a positive electrode, and a negative electrode;
when the positive electrode reference electrode and the negative electrode reference electrode are connected with the switching section, an electric current when a voltage is applied between the positive electrode reference electrode and the negative electrode reference electrode with the voltage applying section is measured with the electric current measuring section; and
when the positive electrode reference electrode and the positive electrode are connected and the negative electrode reference electrode and the negative electrode are connected with the switching section, the potentials of the positive electrode and the negative electrode are measured with the potential measuring sections.
